(19) United States
(12) Patent Application Publication
(10) Pub. No.: US 2012/0049366 A1
(43) Pub. Date: Mar. 1, 2012

(54) PACKAGE STRUCTURE HAVING THROUGH-SILICON-VIA (TSV) CHIP EMBEDDED THEREIN AND FABRICATION METHOD THEREOF

(75) Inventor: Zhao-Chong Zeng, Taoyuan (TW)

(73) Assignee: UNIMICRON TECHNOLOGY CORPORATION, Taoyuan (TW)

(21) Appl. No.: 13/216,715

(22) Filed: Aug. 24, 2011

(30) Foreign Application Priority Data
Aug. 26, 2010 (TW) 099128554

(51) Int. Cl. H01L 23/48; H01L 21/50

(52) U.S. Cl. 257/738; 438/107; 257/E23.011; 257/E21.499

(57) ABSTRACT

A package structure includes a dielectric layer having a first surface and a second surface; a through-silicon-via (TSV) chip embedded in the dielectric layer, wherein the TSV chip has a plurality of conductive TSVs, and electrode pads formed on a surface of the TSV chip that are electrically connected to the conductive TSVs and exposed from the second surface of the dielectric layer; and a first circuit layer formed on the first surface of the dielectric layer, wherein the first circuit layer is connected to the conductive TSVs of the TSV chip by the conductive blind vias, so that the high wiring density semiconductor chip can be disposed on the electrode pads of the TSV chip in order to integrate high wiring density semiconductor chips. The invention also provides a fabrication method for fabricating the package structure having an embedded TSV chip.

### BACKGROUND OF THE INVENTION

1. Field of the Invention

The present invention relates to package structures and fabrication methods thereof, and more particularly, to a package structure having an embedded through-silicon-via (TSV) chip and a fabrication method thereof.

2. Description of Related Art

With the vigorous development of electronic industry, the size of electronic products is trending small and the trend of their functions is towards the Research and Development (R&D) direction of high performance, high functionality, and high speed. In order to satisfy the demand of semiconductor devices with high integration and miniaturization, not only the semiconductor packaging technology of the conventional wire bonding method but also the flip chip method can be used to enhance the wiring density. FIG. 1 shows a schematic cross-sectional view of the conventional flip chip package structure.

Referring to FIG. 1, the package structure includes a package substrate 10 having a first surface 10a and a second surface 10b. The first surface 10a of the package substrate 10 has a plurality of electrical contact pads 100. The electrical contact pads 100 are electrically connected to electrode pads 120 of a semiconductor chip 12 by solder bumps 11. A second surface 10b has a plurality of bump pads 101. The bump pads 101 are electrically connected to a printed circuit board (PCB) (not indicated in FIG. 1).

As the size of electronic products is trending small and the demand for more functionality is continually rising, the wiring density of the semiconductor chip 12 is becoming higher and higher (a nanometer in length per unit). Therefore, the spacing between the electrode pads 120 is smaller. However, the spacing between the electrical contact pads 100 of the package substrate 10 is based on a micrometer in length per unit, and cannot be effectively reduced to the spacing between the electrode pads 120. Although the semiconductor chip 12 has a high wiring density, no compatible package substrates are available. As a result, the electron products cannot be satisfactorily realized.

Therefore, it has become critical to overcome the problems encountered in the prior art.

### SUMMARY OF THE INVENTION

In view of the problems encountered in the prior art, an object of this invention is to provide a package structure having an embedded through-silicon-via (TSV) chip and a fabrication method for integrating high wiring density semiconductor chips.

To achieve these objects above, the present invention provides a package structure having an embedded TSV chip, including: a dielectric layer having a first surface and a second surface, a TSV chip embedded in the dielectric layer, wherein the TSV chip has a plurality of conductive TSVs and electrode pads formed thereon that are electrically connected to the conductive TSVs and exposed from the second surface of the dielectric layer; and a first circuit layer formed on the first surface of the dielectric layer and electrically connected to the conductive TSVs of the TSV chip by conductive vias.

In an embodiment of the present invention, the TSV chip is a silicon TSV chip.

The package structure further comprises a built-up structure formed on the first surface of the dielectric layer and the first circuit layer; and a first solder mask layer formed on the built-up structure, wherein the first solder mask layer has a plurality of first openings for correspondingly exposing a part of the built-up structure that acts as first electrical contact pads.

The package structure further comprises a first chip disposed on and electrically connected to the electrode pads of the TSV chip.

The package structure further comprises a second circuit layer formed on the second surface; a second solder mask layer formed on the second surface of the dielectric layer and the second circuit layer, wherein the second solder mask layer has a plurality of second openings for exposing a part of the second circuit layer that acts as second electrical contact pads; and a plurality of conductive apertures penetrating the dielectric layer to electrically connect the first and the second circuit layers.

The package structure further comprises a semiconductor package electrically connected to the second electrical contact pads by the solder balls, or comprises a second chip disposed on the first chip, wherein the second chip is electrically connected to the second electrical contact pads by bonding wires.

The present invention provides a fabrication method for the package structure having an embedded TSV chip, including: providing a carrier board having a release film formed on each of the two surfaces of the carrier board; coupling a TSV chip having conductive TSVs to the carrier board, wherein the TSV chip has a plurality of electrode pads formed thereon and electrically connected to the conductive TSVs, and the electrode pads are covered by a protective layer, such that the protective layer of the TSV chip is attached to the release film while the TSV chip is coupled to the carrier board; covering the release film and the TSV chip on each of the two surfaces of the carrier board with a dielectric layer, wherein, after a hot pressing process, the TSV chip is embedded in the dielectric layer, and the dielectric layer has a first surface exposed to the ambient and a second surface attached to the release film; forming a first circuit layer on the first surface of the dielectric layer, wherein the first circuit layer is connected to the conductive TSVs of the TSV chip by conductive blind vias; removing the carrier board and the release film formed thereon in order to separate the two dielectric layers on the two surfaces of the carrier board; and removing the protective layer to expose the electrode pads of the TSV chip from the second surface of the dielectric layer.

In an embodiment of the present invention, the TSV chip is a silicon TSV chip.

The fabrication method further comprises: forming a built-up structure on the first surface of the dielectric layer and the first circuit layer; and forming a first solder mask layer on the built-up structure, wherein the first solder mask layer has a plurality of first openings for correspondingly exposing a part of the built-up structure that acts as first electrical contact pads. Furthermore, the fabrication method also includes electrically connecting a first chip to the electrode pads of the TSV chip.

The fabrication method further comprises: forming a second circuit layer on the second surface of the dielectric layer; forming a built-up structure on the first surface of the dielectric layer and the first circuit layer; forming a plurality of conductive apertures in the dielectric layer for electrically connecting the first and the second circuit layers; forming a first solder mask layer on the built-up structure, wherein the first solder mask has a plurality of first openings for correspondingly exposing a part of the built-up structure that acts as first electrical contact pads; forming a second solder mask layer on the second surface of the dielectric layer and the second circuit layer, wherein the second solder mask layer has a plurality of second openings for correspondingly exposing a part of the second circuit layer that acts as second electrical contact pads. The fabrication method also includes electrically connecting a first chip to the electrode pads of the TSV chip.

The fabrication method further comprises a semiconductor package disposed on the second solder mask layer, wherein the semiconductor package is electrically connected to the second electrical contact pads by the solder balls; or includes a second chip disposed on the first chip, wherein the second chip is electrically connected to each of the second electrical contact pads by bonding wires.

In summary, the package structure having an embedded TSV chip and the fabrication method of the present invention are based on the embedded TSV chip enabling the package structure to have the electrical connection pads (the electrode pads of the TSV chip) for the corresponding high wiring density chip (the first chip). Therefore, the purpose of integrating high wiring density semiconductor chips can be achieved.

### BRIEF DESCRIPTION OF THE DRAWINGS

FIG. 1 is a schematic cross-sectional view of known flip chip package structure; and

FIGS. 2A to 2K are schematic cross-sectional views of the embedded TSV chip package structure and a fabrication method according to the present invention; wherein FIG. 2H′ illustrates an alternative embodiment of FIG. 2H; FIG. 2I′ illustrates an alternative embodiment of FIG. 2I; FIG. 2J′ illustrates an alternative embodiment of FIG. 2J; and FIG. 2K illustrates an alternative embodiment of FIG. 2K.

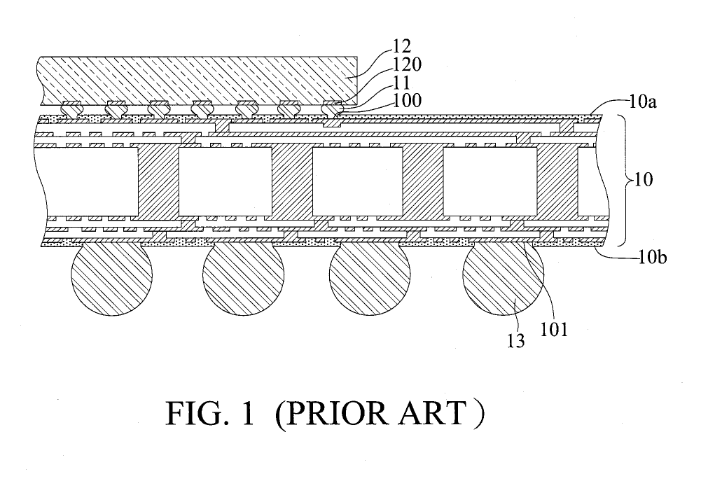

### DETAILED DESCRIPTION OF THE INVENTION

The following embodiments are provided to illustrate the disclosure of the present invention. These and other advantages and effects can be apparent to one ordinarily skilled in the art after reading the disclosure of this specification.

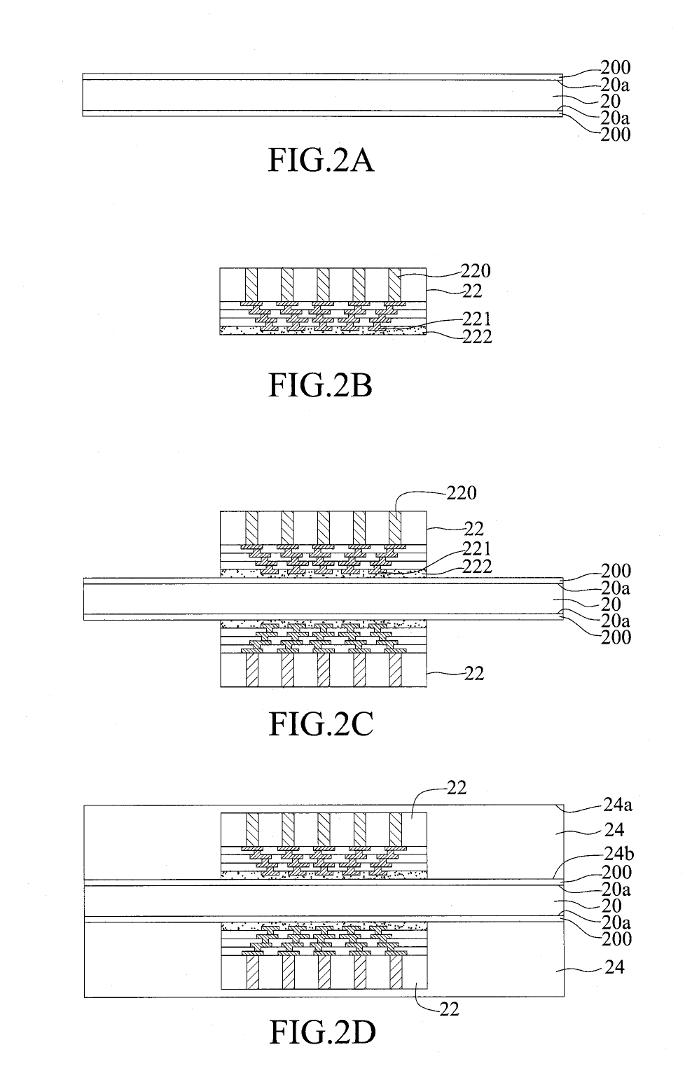

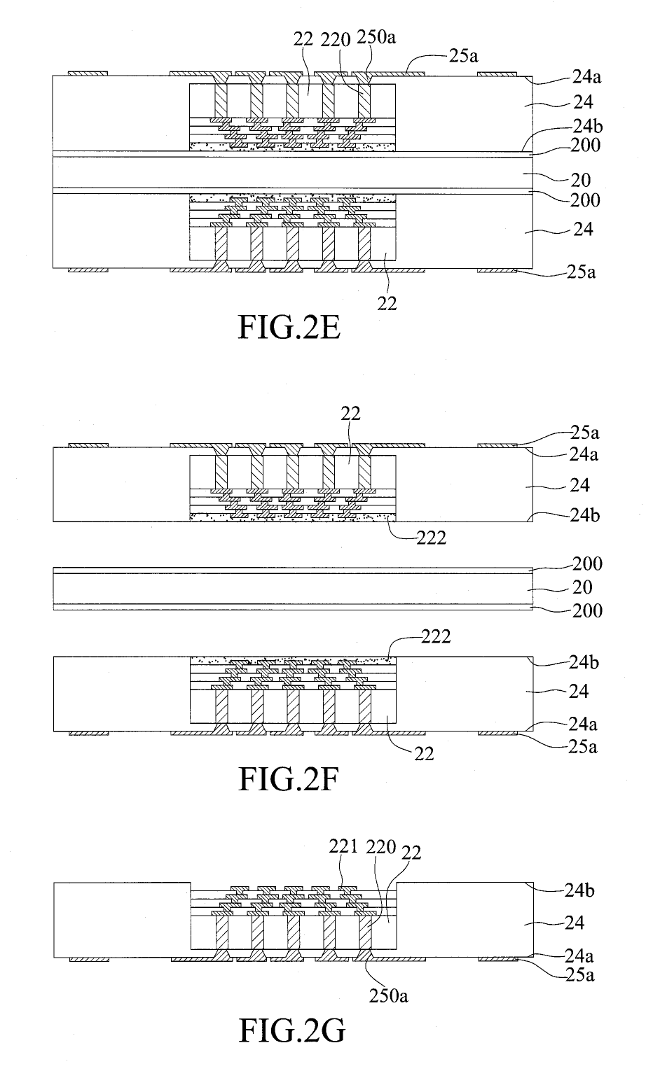

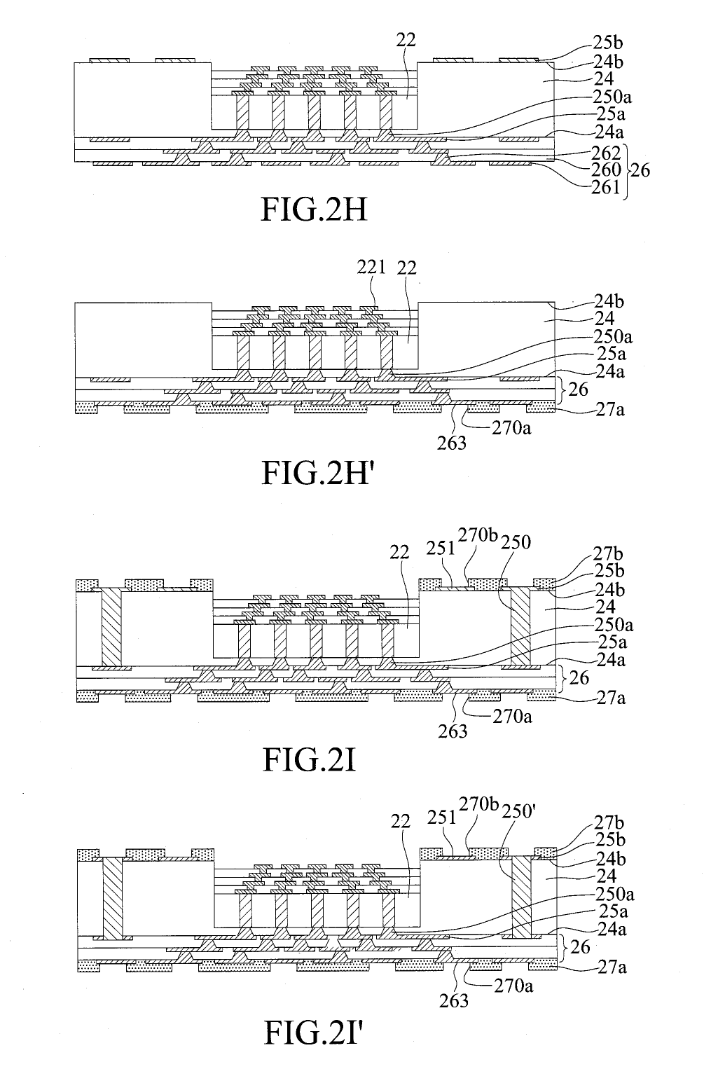

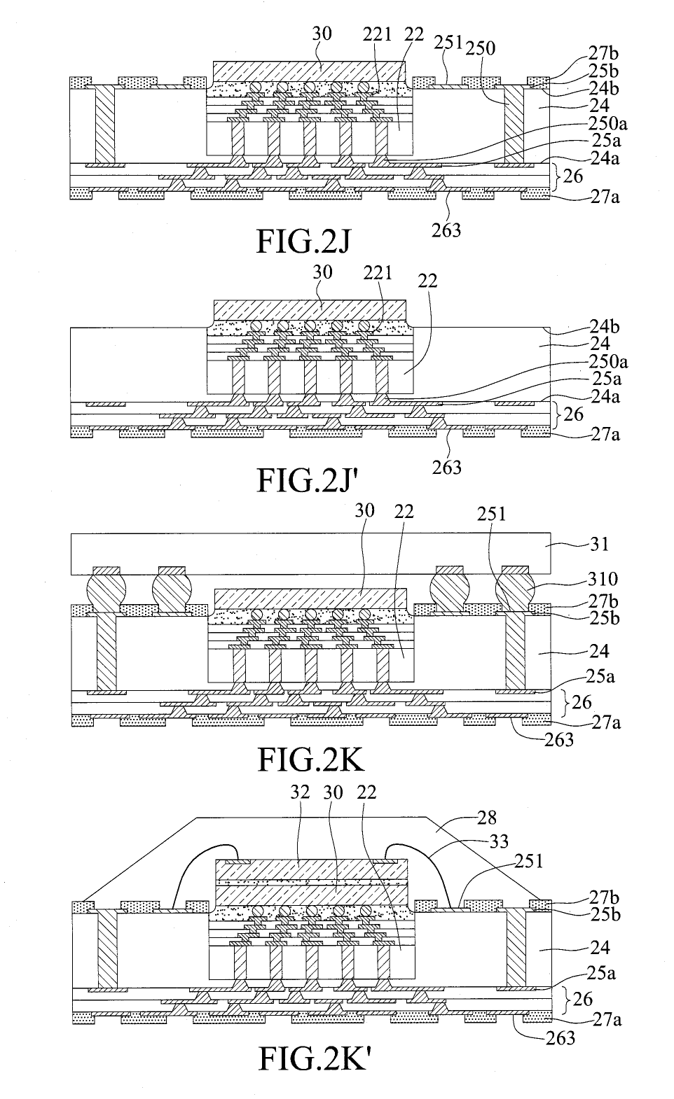

FIGS. 2A to 2I are schematic cross-sectional views illustrating a fabrication method for the package structure having an embedded TSV chip according to the present invention.

As shown in FIGS. 2A and 2B, a carrier board 20 and a TSV chip 22 having a plurality of conductive TSVs 220 are provided. Both surfaces 20a of the carrier board 20 are each covered by a release film 200, respectively.

The TSV chip 22, for example, can be a silicon TSV chip. The conductive TSVs 220 are electrically connected to electrode pads 221. Furthermore, the spacing between any two of the electrode pads 221 is based on a nanometer in length per unit, and the electrode pads 221 are coated by a protective layer 222.

As shown in FIG. 2C, the protective layer 222 of the TSV chip 22 is attached to the release film 200 on each of the two surfaces 20a of the carrier board 20.

As shown in FIG. 2D, the release film 200 on each of the two surfaces 20a of the carrier board 20 and the TSV chip 22 are covered by a dielectric layer 24. After a hot pressing process has been performed, the TSV chip is allowed to be embedded in the dielectric layer 24, and a first surface 24a of the dielectric layer 24 is exposed to the ambient and a second surface 24b of the dielectric layer 24 is attached to the release film 200.

As shown in FIG. 2E, a first circuit layer 25a is formed on the first surface 24a of the dielectric layer 24 and the first circuit layer 25a is electrically connected to the conductive TSVs 220 of the TSV chip 22 by a plurality of conductive blind vias 250a.

As shown in FIG. 2F, the carrier board 20 and the release films 200 formed thereon are removed in order to separate the two dielectric layers 24 respectively formed on the two surfaces of the carrier board 20.

As shown in FIG. 2G, the protective layer 220 of the TSV chip 22 is removed to expose the electrode pads 221 of the TSV chip 22 to the second surface 24b of the dielectric layer 24.

As shown in FIG. 2H, the second circuit layer 25b is formed on the second surface 24b of the dielectric layer 24, and a built-up structure 26 is formed on the first surface 24a of the dielectric layer 24 and the first circuit layer 25a. The built-up structure 26 includes at least a dielectric layer 260, conductive traces 261 on the dielectric layer 260, and a plurality of conductive blind vias 262 (formed in the dielectric layer 260) for electrically connecting the first circuit layer 25a and the conductive traces 261.

As shown in FIG. 2I, with the process of forming the blind vias, when a second circuit layer 25b is formed, a plurality of conductive apertures 250 are also formed in the dielectric layer 24 at the same time. The conductive apertures 250 are used to connect the first circuit layer 25a and the second circuit layer 25b. In addition, a first solder mask layer 27a is formed on the built-up structure 26. The first solder mask layer 27a has a plurality of first openings 270a formed therein for correspondingly exposing a part of the conductive traces 261 of the built-up structure 26 so as for the exposed part of the build-up structure 26 to serve as first electrical contact pads 263. Furthermore, a second solder mask layer 27b is formed on the second surface 24b of the dielectric layer 24 and the second circuit layer 25b. The second solder mask layer 27b has a plurality of second openings 270b formed therein for correspondingly exposing a part of the second circuit layer 25b so as for the exposed part of the second circuit layer 25b to serve as second electrical contact pads 251.

As shown in FIG. 2I′, also with the process of forming the blind vias, after forming the second circuit layer 25b, a plurality of conductive apertures 250′ are then formed in the dielectric layer 24 to electrically connect the first circuit layer 25a and the second circuit layer 25b.

Moreover, FIG. 2H′ continues the subsequent processes of FIG. 2G A built-up structure 26 is formed on the first surface 24a of the dielectric layer 24 and the first circuit layer 25a. Subsequently, a first solder mask layer 27a is formed on the built-up structure 26. The first solder mask layer 27a has a plurality of first openings 270a formed therein for correspondingly exposing a part of the conductive traces 261 of the built-up structure 26 so as for the exposed part of the build-up structure 26 to serve as first electrical pads 263.

FIGS. 2J and 2J′ show the subsequent processes of FIGS. 2I and 2H′, respectively. The electrode pads 221 of the TSV chip are electrically connected to a first chip 30 by the flip chip method.

FIGS. 2K and 2K′ utilize the package structure of FIG. 2J. As shown in FIG. 2K, the second electrical contact pads 251 are electrically connected to a semiconductor package 31 by solder balls 310. The semiconductor package 31, for example, can be a photosensitive package structure. As also shown in FIG. 2K′, a second chip 32 is disposed on the first chip 30. Bonding wires 33 electrically connect the second chip 32 to the electrical contact pads 251. Subsequently, an encapsulant 28 is formed on the second solder mask layer 27b and the first chip 30, such that the second chip 32, the bonding wires 33, and the second electrical contact pads 251 are encapsulated by the encapsulant 28. In addition, the second electrical contact pads 251 can also be connected to other electronic devices, such as passive devices.

The present invention features in that the first chip 30 having high wiring density (a nanometer in length per unit) is allowed to be disposed on the embedded TSV chip and electrically connected to the TSV chip via the electrode pads 221 of the TSV chip. As the high wiring density first chip 30 can be effectively coupled with the package structure of this invention, the purpose of integrating high wiring density semiconductor chips into a single package is thus achieved.

Furthermore, the embedded TSV chip 22 also increase the wiring density of the package structure for improving the electrical functionality.

The present invention further provides a package structure having an embedded TSV chip, having: a dielectric layer 24 having a first surface 24a and a second surface 24b; a TSV chip 22 embedded in the dielectric layer 24, wherein the TSV chip 22 has a plurality of conductive TSVs 220 formed therein for exposing the conductive TSVs 220 to electrode pads 221 on the second surface 24b of the dielectric layer 24; and a first circuit layer 25a formed on the first surface 24a of the dielectric layer 24, wherein the first circuit layer 25a is connected to the conductive TSVs 220 of the TSV chip 22 by conductive blind vias 250a.

The TSV chip 22 can a silicon TSV chip.

According to one embodiment, the package structure further comprises: a built-up structure 26 formed on the first surface 24a of the dielectric layer 24 and the first circuit layer 25a; and a first solder mask layer 27a formed on the built-up structure 26, wherein the first solder mask layer 27a has a plurality of first openings 270a formed therein for correspondingly exposing a part of the conductive traces 261 of the built-up structure 26 so as for the exposed part of the built-up structure to serve as first electrical contact pads 263.

According to the application example of the above structure, the first chip 30 is electrically connected to electrode pads 221 of the TSV chip 22.

According to another embodiment, the package structure also includes: a second circuit layer 25b formed on the second surface 24b of the dielectric layer 24; and a second solder mask layer 27b disposed on the second surface 24b of the dielectric layer 24 and the second circuit layer 25b, wherein the second solder mask layer 27b has a plurality of second openings 270b formed therein for correspondingly exposing parts of the second circuit layer 25b so as for electrical contact pads 251.

According to other embodiments, the package structure still includes a conductive aperture 250 penetrating the dielectric layer 24 to electrically connect to the first circuit layer 25a and the second circuit layer 25b.

According to the application example of the above structure, the first chip 30 is electrically connected to the electrode pads 221 of the TSV chip 22. In addition, a semiconductor package 31 is connected to the second electrical contact pads 251 by solder balls 310, or the second chip 32 is disposed on the first chip 30. Furthermore, the second chip 32 is connected to the second electrical contact pads 251 by wires 33.

In summary, the package structure having an embedded TSV chip and the fabrication method of the present invention are based on an embedded TSV chip to increase the package structure wiring density for improving the electrical functionality. Furthermore, high wiring density chip can be effectively disposed in order to achieve the purpose of integrating high wiring density semiconductor chips.

The above descriptions of the embodiments are only to illustrate the preferred implementation according to the present invention, and it is not to limit the scope of the present invention. Accordingly, all modifications and variations completed by those with one skill in the art should fall within the scope of the present invention defined via the appended claims.

What is claimed is:

1. A package structure having an embedded through-silicon-via (TSV) chip, comprising:
a dielectric layer having a first surface and a second surface opposing the first surface;
a TSV chip embedded in the dielectric layer, wherein the TSV chip has a plurality of conductive TSVs, and electrode pads formed on a surface of the TSV chip that are electrically connected to the conductive TSVs and exposed from the second surface of the dielectric layer; and
a first circuit layer formed on the first surface of the dielectric layer and electrically connected to the conductive TSVs of the TSV chip by conductive vias.

2. The package structure of claim 1, wherein the embedded TSV chip is a silicon TSV chip.

3. The package structure of claim 1, further comprising a built-up structure formed on the first surface of the dielectric layer and the first circuit layer.

4. The package structure of claim 3, further comprising a first solder mask layer formed on the built-up structure and having a plurality of first openings for exposing a part of the built-up structure that acts as first electrical contact pads.

5. The package structure of claim 4, further comprising a first chip disposed on and electrically connected to the electrode pads of the TSV chip.

6. The package structure of claim 5, further comprising a second circuit layer formed on the second surface of the dielectric layer.

7. The package structure of claim 6, further comprising a second solder mask layer formed on the second surface of the dielectric layer and having a plurality of second electrical contact pads for exposing a part of the second circuit layer that acts as second electrical contact pads.

8. The package structure of claim 7, further comprising a plurality of conductive apertures penetrating the dielectric layer and electrically connected to the first circuit layer and the second circuit layer.

9. The package structure of claim 7, further comprising a semiconductor package electrically connected to the second electrical contact pads by solder balls.

10. The package structure of claim 7, further comprising a second chip disposed on the first chip and electrically connected to the second electrical contact pads via bonding wires.

11. A method of fabricating a package structure, comprising the steps of:
providing a carrier board having release films formed on both surfaces of the carrier board;
coupling at least a TSV chip having conductive TSVs to each of the surface of the carrier board, wherein the TSV chip has a plurality of electrode pads formed thereon and electrically connected to the conductive TSVs, and the electrode pads are covered by a protective layer, such that the protective layer of the TSV chip is attached to the release film, while the TSV chip is coupled to the carrier board;
covering the release film and the TSV chip on each of the surfaces of surfaces of the carrier board with a dielectric layer, wherein, after a hot pressing process, the TSV chip coupled to each of the surfaces of the carrier board is allowed to be embedded in the dielectric layer, and the dielectric layer has a first surface exposed to the ambient and a second surface attached to the release film;
forming a first circuit layer on the first surface of the dielectric layer, wherein the first circuit layer is connected to the conductive TSVs of the TSV chip by conductive blind vias;
removing the carrier board and the release films formed thereon in order to separate the two dielectric layers on the two surfaces of the carrier board; and
removing the protective layer to expose the electrode pads of the TSV chip from the second surface of the dielectric layer.

12. The method of claim 11, wherein the TSV chip is a silicon TSV chip.

13. The method of claim 11, further comprising:
forming a built-up structure on the first surface of the dielectric layer and the first circuit layer; and
forming a first solder mask layer on the built-up structure, wherein the first solder mask layer has a plurality of first openings for correspondingly exposing a part of the built-up structure that acts as first electrical contact pads.

14. The method of claim 13, further comprising electrically connecting the electrode pads of the TSV chip to the first chip.

15. The method of claim 11, further comprising:
forming a second circuit layer on the second surface of the dielectric layer;
forming a built-up structure on the first surface of the dielectric layer and the first circuit layer;
forming in the dielectric layer a plurality of conductive apertures for electrically connecting the first and the second circuit layer;
forming a first solder mask layer on the built-up structure, wherein the first solder mask layer has a plurality of first openings for correspondingly exposing a part of the built-up structure that acts as first electrical contact pads; and
forming a second solder mask layer on the second surface of the dielectric layer and the second circuit layer, wherein the second solder mask layer has a plurality of second openings for correspondingly exposing a part of the second circuit layer that acts as second electrical contact pads.

16. The method of claim 15, further comprising electrically connecting the electrode pads of the TSV chip to the first chip.

17. The method of claim 16, further comprising disposing a semiconductor package on the second solder mask layer, wherein the semiconductor package is electrically connected to the second electrical contact pads by solder balls.

18. The method of claim 16, further comprising disposing a second chip on the first chip, wherein the second chip is electrically connected to the second electrical contact pads by bonding wires.
